(19) United States
(12) Patent Application Publication
(10) Pub. No.: US 2025/0287594 A1
(43) Pub. Date: Sep. 11, 2025

(54) SEMICONDUCTOR DEVICE MANUFACTURING METHOD

(71) Applicant: Samsung Electronics Co., Ltd., Suwon-si (KR)

(72) Inventor: Daehwan Choi, Suwon-si (KR)

(21) Appl. No.: 19/001,704

(22) Filed: Dec. 26, 2024

(30) Foreign Application Priority Data
Mar. 8, 2024 (KR) 10-2024-0033325

(51) Int. Cl. H10B 43/27; H10B 43/10; H10B 51/10; H10B 51/20

(52) U.S. Cl. CPC H10B 43/27; H10B 43/10; H10B 51/10; H10B 51/20

(57) ABSTRACT

Provided is a semiconductor device manufacturing method including forming a mold stack by alternately forming a plurality of sacrificial layers and a plurality of mold insulating layers on a substrate, forming a plurality of contact plug holes each extending in the mold stack in a vertical direction and spaced apart from a bottom surface of the mold stack by a first distance, forming a photoresist layer on the mold stack and the contact plug holes, forming a photoresist pattern by patterning the photoresist layer, and extending ones of the contact plug holes in the vertical direction by etching the mold stack using the photoresist pattern. Forming the photoresist pattern may include removing a portion of the photoresist layer on the contact plug holes. The photoresist pattern may include an opening exposing an upper surface of the mold stack and a side photoresist pattern on a sidewall of the mold stack.

### CROSS-REFERENCE TO RELATED APPLICATIONS

This application is based on and claims priority under 35 U.S.C. § 119 to Korean Patent Application No. 10-2024-0033325, filed on Mar. 8, 2024, in the Korean Intellectual Property Office, the disclosure of which is incorporated by reference herein in its entirety.

### BACKGROUND OF THE INVENTION

The inventive concepts relate to a semiconductor device manufacturing method, and more particularly, to a method of manufacturing a semiconductor device having a vertical channel.

In electronic systems that require data storage, semiconductor devices capable of storing high-capacity data are helpful. Accordingly, a method capable of increasing the data storage capacity of a semiconductor device is being studied. For example, as one method for increasing the data storage capacity of a semiconductor device, semiconductor devices including memory cells arranged three-dimensionally instead of two-dimensionally have been proposed.

### SUMMARY OF THE INVENTION

The inventive concepts provide a semiconductor device manufacturing method having improved integration and excellent electrical characteristics.

The task to be solved by the technical idea of the inventive concepts is not limited to the above-mentioned task, and other tasks not mentioned will be clearly understood by those of ordinary skill in the art from the following description.

According to aspects of the inventive concepts, there is provided a semiconductor device manufacturing method including forming a mold stack by alternately forming a plurality of sacrificial layers and a plurality of mold insulating layers on a substrate, forming a plurality of contact plug holes each extending in the mold stack in a vertical direction and spaced apart from a bottom surface of the mold stack by a first distance, forming a photoresist layer on the mold stack and the plurality of contact plug holes, forming a photoresist pattern by patterning the photoresist layer, and extending ones of the plurality of contact plug holes in the vertical direction by etching the mold stack using the photoresist pattern, wherein forming the photoresist pattern includes removing a portion of the photoresist layer on the plurality of contact plug holes, and wherein the photoresist pattern includes an opening exposing an upper surface of the mold stack and a side photoresist pattern on a sidewall of the mold stack.

According to aspects of the inventive concepts, there is provided a semiconductor device manufacturing method including forming a mold stack by alternately forming a plurality of sacrificial layers and a plurality of mold insulating layers on a substrate, forming a hard mask on the mold stack, forming a plurality of contact plug holes each extending in the mold stack and the hard mask in a vertical direction and spaced apart from a bottom surface of the mold stack by a first distance, forming a photoresist layer on the mold stack, the hard mask, and the plurality of contact plug holes, forming a photoresist pattern by patterning the photoresist layer, and extending ones of the plurality of contact plug holes in the vertical direction by etching the mold stack using the photoresist pattern, wherein forming the photoresist pattern includes removing a portion of the photoresist layer on the plurality of contact plug holes, and wherein the photoresist pattern includes an opening exposing an upper surface of the mold stack and a side photoresist pattern on a sidewall of the mold stack.

According to aspects of the inventive concepts, there is provided a semiconductor device manufacturing method including forming a mold stack by alternately forming a plurality of sacrificial layers and a plurality of mold insulating layers on a substrate, forming a stack cover insulating layer on the mold stack, forming a plurality of contact plug holes each extending in the mold stack and the stack cover insulating layer in a vertical direction and spaced apart from a bottom surface of the mold stack by a first distance, forming a photoresist layer on the mold stack and the plurality of contact plug holes, forming a photoresist pattern by patterning the photoresist layer, the photoresist pattern including an opening exposing an upper surface of the mold stack and a side photoresist pattern on a sidewall of the mold stack, extending ones of the plurality of contact plug holes in the vertical direction by etching the mold stack using the photoresist pattern, forming an insulating spacer in the plurality of contact plug holes, replacing the plurality of sacrificial layers with a plurality of gate electrodes, exposing a top surface of each of the plurality of gate electrodes by removing a portion of the insulating spacer in each of the plurality of contact plug holes, and forming a plurality of contact plugs in the plurality of contact plug holes, respectively, and electrically connected to the plurality of gate electrodes, respectively.

### BRIEF DESCRIPTION OF THE DRAWINGS

Example embodiments of the inventive concepts will be more clearly understood from the following detailed description taken in conjunction with the accompanying drawings, in which:

FIG. 1 is a block diagram of a semiconductor device according to embodiments;

FIG. 2 is an equivalent circuit diagram of a memory cell array of a semiconductor device according to embodiments;

FIG. 3 is a perspective view illustrating a representative configuration of a semiconductor device according to embodiments;

FIG. 4 is a plan view showing the semiconductor device of FIG. 3;

FIG. 5 is a cross-sectional view taken along line A-A′ of FIG. 4;

FIGS. 6 to 9, 10A, 10B, 11 to 16, 17A, 17B, 18, and 19 are cross-sectional views illustrating a method of manufacturing a semiconductor device according to embodiments and are an enlarged view of a portion EX1 of FIG. 5; and

FIGS. 20 to 26 are cross-sectional views illustrating a method of manufacturing a semiconductor device according to embodiments and are an enlarged view of the portion EX1 of FIG. 5.

### DETAILED DESCRIPTION

Hereinafter, example embodiments of the inventive concepts will be described in detail with reference to the accompanying drawings. The same reference numerals are used for the same components in the drawings, and redundant descriptions thereof may be omitted.

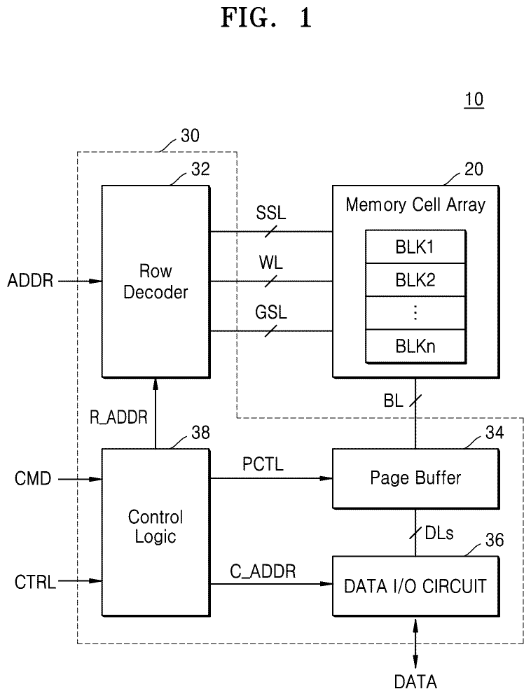

FIG. 1 is a block diagram of a semiconductor device 10 according to embodiments.

Referring to FIG. 1, a semiconductor device 10 may include a memory cell array 20 and a peripheral circuit 30. The memory cell array 20 includes a plurality of memory cell blocks BLK1, BLK2, . . . , and BLKn. Each of the plurality of memory cell blocks BLK1, BLK2, . . . , and BLKn may include a plurality of memory cells. The memory cell blocks BLK1, BLK2, . . . , and BLKn may be connected to the peripheral circuit 30 through a bit line BL, a word line WL, a string selection line SSL, and a ground selection line GSL.

The peripheral circuit 30 may include a row decoder 32, a page buffer 34, a data input/output (I/O) circuit 36, and a control logic 38. Although not shown in FIG. 1, the peripheral circuit 30 may further include an input/output interface, a column logic, a voltage generation unit, a pre-decoder, a temperature sensor, a command decoder, an address decoder, an amplification circuit, and the like.

The memory cell array 20 may be connected to the page buffer 34 through the bit line BL, and may be connected to the row decoder 32 through the word line WL, the string selection line SSL, and the ground selection line GSL. In the memory cell array 20, each of the plurality of memory cells included in each of the plurality of memory cell blocks BLK1, BLK2, . . . , and BLKn may be a flash memory cell. The memory cell array 20 may include a three-dimensional memory cell array. The three-dimensional memory cell array may include a plurality of NAND strings, and each NAND string may include a plurality of memory cells connected to a plurality of word lines WL vertically stacked on a substrate.

The peripheral circuit 30 may receive an address ADDR, a command CMD, and a control signal CTRL from the outside of the semiconductor device 10 (i.e., externally), and may transmit and receive data DATA to and from a device outside (i.e., external to) the semiconductor device 10.

The row decoder 32 may select at least one of a plurality of memory cell blocks BLK1, BLK2, . . . , and BLKn in response to an address ADDR from the outside, and may select a word line WL, a string selection line SSL, and a ground selection line GSL of the selected memory cell block. The row decoder 32 may transfer a voltage for performing a memory operation to the word line WL of the selected memory cell block.

The page buffer 34 may be connected to the memory cell array 20 through the bit line BL. The page buffer 34 may operate as a write driver during a program operation to apply a voltage according to the data DATA to be stored in the memory cell array 20 to the bit line BL, and may operate as a sense amplifier during a read operation to sense the data DATA stored in the memory cell array 20. The page buffer 34 may operate according to a control signal PCTL provided from the control logic 38.

The data input/output circuit 36 may be connected to the page buffer 34 through data lines DLs. The data I/O circuit 36 may receive data DATA from a memory controller (not shown) during a program operation and provide program data DATA to the page buffer 34 based on a column address C_ADDR provided from the control logic 38. The data I/O circuit 36 may provide read data DATA stored in the page buffer 34 to the memory controller based on the column address C_ADDR provided from the control logic 38 during a read operation.

The data I/O circuit 36 may transmit an input address or instruction to the control logic 38 or the row decoder 32. The peripheral circuit 30 may further include an electrostatic discharge (ESD) circuit and a pull-up/pull-down driver.

The control logic 38 may receive a command CMD and a control signal CTRL from the memory controller (not shown). The control logic 38 may provide a row address R_ADDR to the row decoder 32 and provide a column address C_ADDR to the data I/O circuit 36. The control logic 38 may generate various internal control signals used in the semiconductor device 10 in response to the control signal CTRL. For example, the control logic 38 may adjust a voltage level provided to the word line WL and the bit line BL when performing a memory operation such as a program operation or an erase operation.

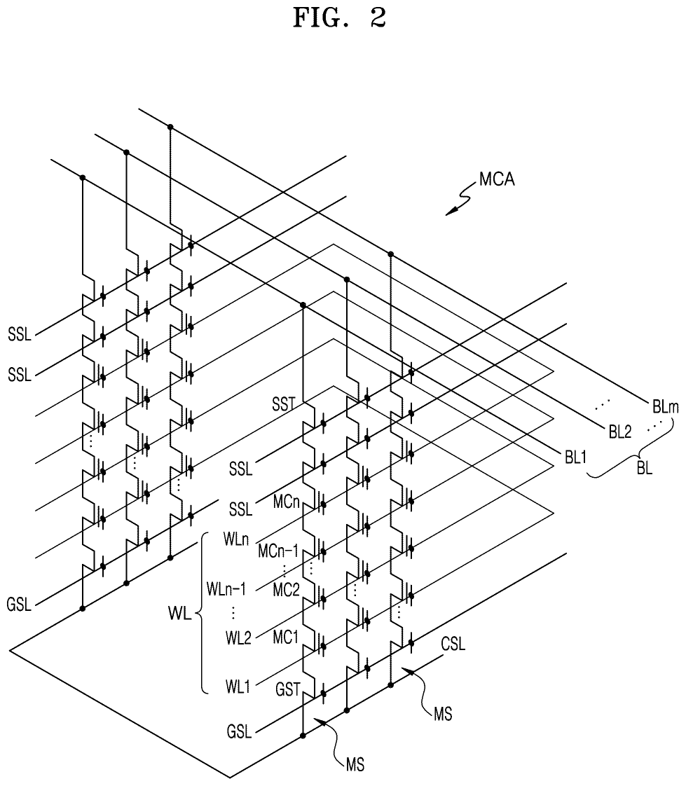

FIG. 2 is an equivalent circuit diagram of a memory cell array of a semiconductor device 10 according to embodiments.

Referring to FIG. 2, a memory cell array MCA may include a plurality of memory cell strings MS. The memory cell array MCA may include a plurality of bit lines BL: BL1, BL2, . . . , and BLm, a plurality of word lines WL: WL1, WL2, . . . , WLn−1 and WLn, at least one string selection line SSL, at least one ground selection line GSL, and a common source line CSL. The plurality of memory cell strings MS may be formed between the plurality of bit lines BL: BL1, BL2, . . . , and BLm, and the common source line CSL. Although FIG. 2 illustrates a case where each of a plurality of memory cell strings MS includes two string selection lines SSL, embodiments of the inventive concepts are not limited thereto. For example, each of the plurality of memory cell strings MS may include one string selection line SSL.

Each of the plurality of memory cell strings MS includes a string selection transistor SST, a ground selection transistor GST, and a plurality of memory cell transistors MC1, MC2 . . . , MCn−1 and MCn. A drain region of the string selection transistor SST may be connected to the bit lines BL: BL1, BL2, . . . , and BLm, and a source region of the ground selection transistor GST may be connected to the common source line CSL. The common source line CSL may be a region to which source regions of the plurality of ground selection transistors GST are commonly connected.

The string selection transistor SST may be connected to the string selection line SSL, and the ground selection transistor GST may be connected to the ground selection line GSL. Each of a plurality of memory cell transistors MC1, MC2, . . . , MCn−1 and MCn may be connected to a plurality of word lines WL: WL1, WL2, . . . , WLn−1 and WLn.

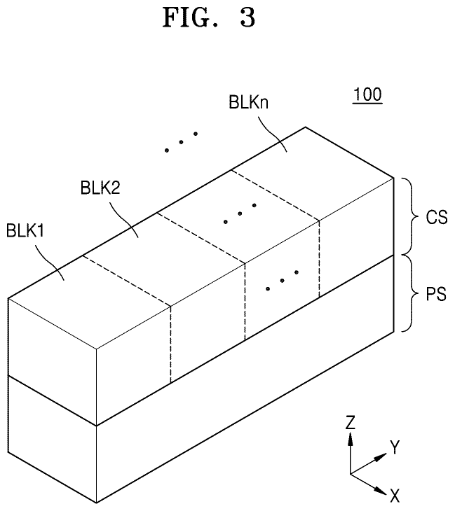

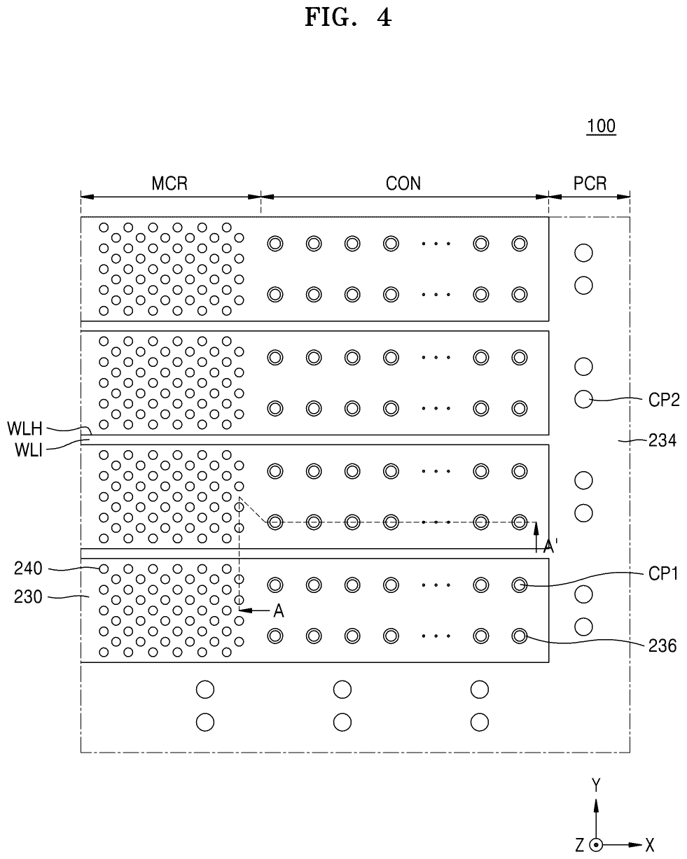

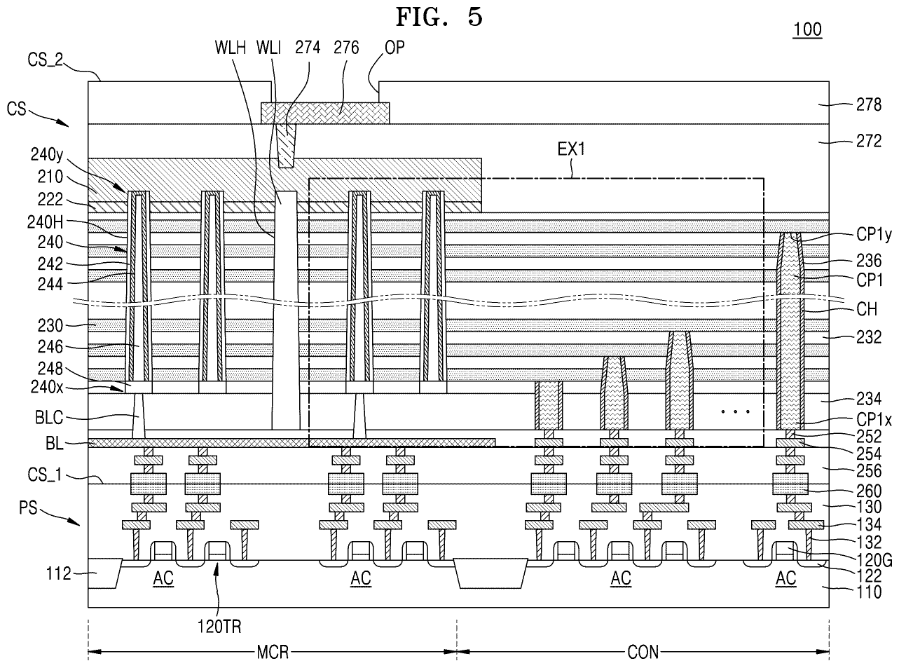

FIG. 3 is a perspective view illustrating a representative configuration of a semiconductor device 100 according to embodiments. FIG. 4 is a plan view showing the semiconductor device 100 of FIG. 3. FIG. 5 is a cross-sectional view taken along line A-A′ of FIG. 4.

Referring to FIGS. 3 to 5, a semiconductor device 100 includes a cell structure CS and a peripheral circuit structure PS, which overlap each other in a vertical direction Z. As used herein, “an element A overlaps an element B in a direction” (or similar language) means that there is at least one straight line that extends in the direction and intersects both the elements A and B. The cell structure CS may include the memory cell array 20 described with reference to FIG. 1, and the peripheral circuit structure PS may include the peripheral circuit 30 described with reference to FIG. 1.

The cell structure CS may include a plurality of memory cell blocks BLK1, BLK2, . . . , and BLKn. Each of the plurality of memory cell blocks BLK1, BLK2, . . . , and BLKn may include memory cells, which are three-dimensionally arranged.

The peripheral circuit structure PS may include peripheral circuit transistors 120TR arranged on a substrate 110. An active region AC may be defined on the substrate 110 by a device isolation layer 112, and the plurality of peripheral circuit transistors 120TR may be formed on the active region AC. Each of the plurality of peripheral circuit transistors 120TR may include a peripheral circuit gate 120G and a source/drain region 122 arranged on both (i.e., opposite) sides of the peripheral circuit gate 120G on a portion of the substrate 110.

The substrate 110 may include a semiconductor material, for example, a group IV semiconductor, a group III-V compound semiconductor, or a group II-VI oxide semiconductor. For example, the group IV semiconductor may include silicon (Si), germanium (Ge), or silicon-germanium (SiGe). The substrate 110 may be provided as a bulk wafer or an epitaxial layer. In other embodiments, the substrate 110 may include a silicon-on-insulator (SOI) substrate or a germanium-on-insulator (GeOI) substrate.

A plurality of peripheral circuit contacts 132 and a plurality of peripheral circuit wiring layers 134 may be arranged on a top surface of the substrate 110. An interlayer insulating layer 130 on (e.g., covering) the peripheral circuit transistors 120TR, the plurality of peripheral circuit contacts 132, and the plurality of peripheral circuit wiring layers 134 may be arranged on the substrate 110. The plurality of peripheral circuit wiring layers 134 may have a multilayer structure including a plurality of metal layers arranged at different vertical levels. As used herein, the term “vertical level” may refer to a height or distance in a vertical direction (e.g., the vertical direction Z) from a bottom surface of the substrate 110. Although not specifically shown in FIG. 5, the vertical direction Z may be substantially perpendicular to the bottom surface of the substrate 110. Connection pads 260 may be arranged on the interlayer insulating layer 130, and the peripheral circuit structure PS and the cell structure CS may be electrically connected and bonded to each other by the connection pads 260.

The cell structure CS may include a cell region MCR, a connection region CON, and a peripheral circuit connection region PCR. The cell region MCR may be a region in which a memory cell block BLK including a plurality of memory cell strings extending in the vertical direction Z is arranged. A common source layer 210, a plurality of gate electrodes 230, and a channel structure 240 extending in the vertical direction Z through the gate electrodes 230 and connected to the common source layer 210 may be arranged in the cell region MCR. The plurality of gate electrodes 230 and a plurality of contact plugs CP1 electrically connected to the plurality of gate electrodes 230, respectively, may be arranged in the connection region CON. A peripheral plug CP2 extending in the vertical direction Z and electrically connected to the peripheral circuit wiring layer 134 may be arranged in the peripheral circuit connection region PCR.

The cell structure CS may include a first surface CS_1 connected to the peripheral circuit structure PS and a second surface CS_2 opposite to the first surface CS_1. In the drawings, the first surface CS_1 of the cell structure CS is arranged at a lower side of the cell structure CS, and the second surface CS_2 of the cell structure CS is arranged at an upper side of the cell structure CS.

The gate electrodes 230 may be arranged to be spaced apart from each other in the vertical direction Z in the cell region MCR and the connection region CON, and the gate electrodes 230 may be alternately arranged with the mold insulating layers 232. The gate electrodes 230 spaced apart from each other in the vertical direction Z may have the same width in the first horizontal direction X. Although not specifically shown in FIG. 5, the first horizontal direction X may be substantially parallel to the bottom surface of the substrate 110.

In embodiments, the gate electrodes 230 may include a metal such as tungsten, nickel, cobalt, tantalum, etc., a metal silicide such as tungsten silicide, nickel silicide, cobalt silicide, tantalum silicide, etc., doped polysilicon, or a combination thereof.

In embodiments, the gate electrodes 230 may correspond to ground selection lines GSL, word lines WL, and at least one string selection line SSL constituting the memory cell strings MS (see FIG. 2). For example, the uppermost gate electrode 230 may function as the ground selection line GSL, the lowermost two gate electrodes 230 may function as the string selection lines SSL, and the remaining gate electrodes 230 may function as the word lines WL. Accordingly, the memory cell strings MS connected in series with the ground selection transistor GST, the string selection transistor SST, and the memory cell transistors MC1, MC2 . . . , MCn−1 and MCn therebetween may be provided. In some embodiments, at least one of the gate electrodes 230 may function as a dummy word line, but is not limited thereto.

A stack isolation insulating layer WLI may be arranged in a stack isolation opening WLH penetrating (i.e., extending in) the gate electrodes 230 and the mold insulating layers 232 and extending in the vertical direction Z. The stack isolation insulating layer WLI may have a top surface arranged at a higher vertical level than the uppermost gate electrode 230, and may protrude upward with respect to the uppermost gate electrode 230. In some embodiments, the gate electrodes 230 arranged between a pair of the stack isolation openings WLH may constitute one block.

The channel structure 240 may be arranged in a channel hole 240H extending in the vertical direction through the gate electrodes 230 and the mold insulating layers 232. The channel structure 240 may include a gate insulating layer 242, a channel layer 244, a buried insulating layer 246, and a drain region 248. The gate insulating layer 242, the channel layer 244, and the buried insulating layer 246 may be sequentially arranged on the inner wall of the channel hole 240H.

The channel structure 240 may include a first end 240x arranged close to the peripheral circuit structure PS and a second end 240y opposite to the first end 240x. In embodiments, the channel structure 240 may have an inclined sidewall such that the width of the first end 240x is greater than the width of the second end 240y.

The drain region 248 electrically connected to the channel layer 244 may be arranged at the first end 240x of the channel structure 240. The drain region 248 may be connected to a bit line contact BLC, and the channel layer 244 may be electrically connected to the bit line BL through the drain region 248 and the bit line contact BLC. In the second end 240y of the channel structure 240, the top surface of the channel layer 244 may not be covered by the gate insulating layer 242, and a common source layer 210 may be connected to the top surface of the channel layer 244.

In some embodiments, the gate insulating layer 242 may have a structure that sequentially includes a tunneling dielectric layer, a charge storage layer, and a blocking dielectric layer on an outer wall of the channel layer 244. The charge storage layer is a region in which electrons passing through the tunneling dielectric layer from the channel layer 244 may be stored, and may include silicon nitride, boron nitride, silicon boron nitride, or polysilicon doped with impurities.

In some embodiments, the charge storage layer may include a ferroelectric dielectric material. In this case, the charge storage layer may include a metal oxide having ferroelectric material properties. For example, the charge storage layer may include a ferroelectric material capable of storing data by hysteresis behavior by the voltage applied to the charge storage layer. In embodiments, the charge storage layer may include at least one of hafnium oxide, zirconium oxide, or hafnium zirconium oxide.

An etching stop layer 222 may be arranged on the uppermost gate electrode 230, and the etching stop layer 222 may include polysilicon. In some embodiments, the etching stop layer 222 may be omitted.

The common source layer 210 may be conformally formed on the etching stop layer 222 to be connected to the second end 240y of the channel structure 240 and to be on (e.g., to cover) the top surface of the stack isolation insulating layer WLI. When viewed in a plan view, the common source layer 210 may be arranged on the entire region of the cell region MCR.

In embodiments, the common source layer 210 may include at least one of silicon (Si), germanium (Ge), silicon germanium (SiGe), gallium arsenide (GaAs), indium gallium arsenide (InGaAs), aluminum gallium arsenide (AlGaAs), or a combination thereof. In addition, the common source layer 210 may include a semiconductor doped with n-type impurities. In addition, the common source layer 210 may have a crystal structure including at least one selected from single crystals, amorphous, or polycrystalline. For example, the common source layer 210 may include polysilicon doped with n-type impurities.

A connection via 252, a connection wiring layer 254, and an interlayer insulating layer 256 surrounding the connection via 252 and the connection wiring layer 254 may be arranged between a stack cover insulating layer 234 and the peripheral circuit structure PS. The connection via 252 and the connection wiring layer 254 may be formed in multiple layers to be arranged at a plurality of vertical levels, and the bit lines BL, the contact plugs CP1, and the peripheral plugs CP2 may be electrically connected to the peripheral circuit structure PS through the connection pads 260.

The plurality of gate electrodes 230 may extend in a horizontal direction on the cell region MCR and the connection region CON. The plurality of gate electrodes 230 may overlap each other in a vertical direction on the connection region CON. For example, the plurality of gate electrodes 230 arranged at different vertical levels on the connection region CON may have the same width in the horizontal direction.

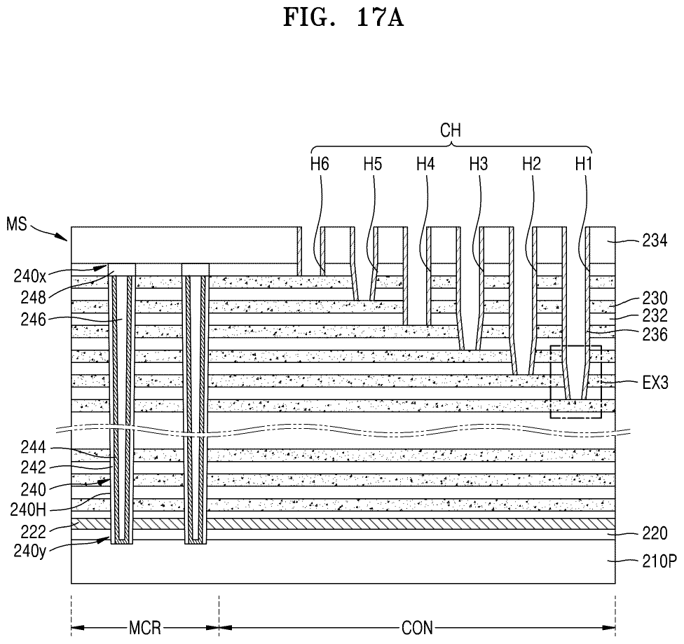

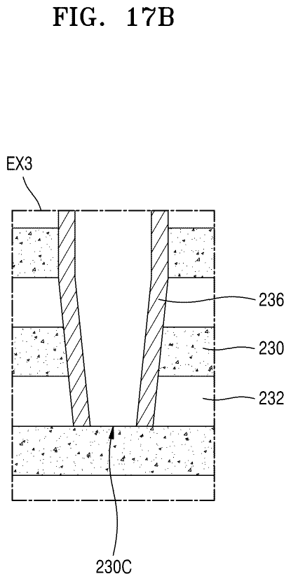

The plurality of contact plugs CP1 may penetrate the stack cover insulating layer 234, the mold insulating layer 232, and the gate electrodes 230 on the connection region CON to extend in the vertical direction Z. The plurality of contact plugs CP1 may have heights varying in the vertical direction Z. In embodiments, each of the plurality of contact plugs CP1 has a first end CP1x and a second end CP1y, and the first ends CP1x of the plurality of contact plugs CP1 may all be arranged at the same vertical level, and may also be arranged at the same vertical level as the bottom surface of the stack cover insulating layer 234. The second ends CP1y of the plurality of contact plugs CP1 may be arranged at different vertical levels, and for example, the second ends CP1y of the plurality of contact plugs CP1 may be placed on corresponding gate contact surfaces 230C (see FIG. 17B), respectively.

In embodiments, a surface of each of the plurality of contact plugs CP1 may be in contact with a gate contact surface 230C, and accordingly, one contact plug CP1 may be electrically connected to the corresponding gate electrode 230 through the gate contact surface 230C. In embodiments, a sidewall of each of the plurality of contact plugs CP1 may be surrounded by an insulating spacer 236. For example, a corresponding insulating spacer 236 may be arranged between the contact plug CP1 and the gate electrodes 230 corresponding to one of the plurality of contact plugs CP1.

In embodiments, a plurality of contact plug holes CH may have an inclined shape in which a width in a horizontal direction decreases from the first end CP1x of the contact plug CP1 toward the second end CP1y of the contact plug CP1. In this case, the contact plug hole CH may include a smooth sidewall without a step-shaped protrusion. Accordingly, the plurality of contact plugs CP1 may have an inclined shape in which a width in a horizontal direction decreases from the first end CP1x toward the second end CP1y. In addition, the contact plug CP1 may include a smooth sidewall without a step-shaped protrusion.

In embodiments, the top surface of one contact plug CP1 may be electrically connected to the corresponding gate electrode 230, while the sidewall of one contact plug CP1 may not be electrically connected to the gate electrode(s) 230 arranged at a lower vertical level than the corresponding gate electrode 230. An insulating spacer 236 may be arranged between the gate electrode(s) 230 arranged at a vertical level lower than the corresponding gate electrode 230 and the sidewall of the one contact plug CP1, and accordingly, the gate electrode(s) 230 arranged at a vertical level lower than the corresponding gate electrode 230 and the sidewall of the one contact plug CP1 may be insulated from each other. Here, the gate electrode(s) 230 arranged at a lower vertical level than the corresponding gate electrode 230 may indicate the gate electrode(s) 230 arranged closer to the peripheral circuit structure PS than the corresponding gate electrode 230.

In embodiments, the contact plugs CP1 may include a metal such as tungsten, nickel, cobalt, tantalum, etc., a metal silicide such as tungsten silicide, nickel silicide, cobalt silicide, tantalum silicide, etc., doped polysilicon, or a combination thereof. In embodiments, the insulating spacer 236 may include silicon oxide. In some embodiments, the insulating spacer 236 may include a silicon oxide containing a small amount of any one of chlorine, fluorine, or bromine (e.g., 5 atomic percent (at %) or less).

In embodiments, the insulating spacer 236 may have a ring-shaped horizontal cross section. In other words, the insulating spacer 236 may have a ring-shape when viewed in a plan view (i.e., when viewed from above). In addition, the insulating spacer 236 may have an inclined shape in which the width in the horizontal direction decreases from the first end CP1x of the contact plug CP1 toward the second end CP1y of the contact plug CP1. However, embodiments are not limited thereto, and the width of the insulating spacer 236 in the horizontal direction may be vertically constant.

In embodiments, the insulating spacer 236 may be conformally arranged on the contact plug hole CH. Accordingly, the insulating spacer 236 may include a smooth sidewall without a step-shaped protrusion.

An upper insulating layer 272 may be arranged on the common source layer 210. The upper insulating layer 272 may have a flat top surface over the entire cell region MCR and the entire connection region CON. A common source contact 274 penetrating the upper insulating layer 272 and connected to the common source layer 210 may be arranged, and a rear wiring layer 276 electrically connected to the common source contact 274 may be arranged on the upper insulating layer 272.

A passivation layer 278 on the rear wiring layer 276 may be arranged on the upper insulation layer 272. The passivation layer 278 may include an opening OP exposing a top surface of the rear wiring layer 276.

Although not shown, dummy channels (not shown) extending in the vertical direction Z through the gate electrodes 230 and the mold insulating layers 232 in the connection region CON may be further formed. The dummy channels may be formed to prevent leaning or bending of the gate electrodes 230 in a manufacturing process of the semiconductor device 100 and to secure structural stability.

In general, a contact plug is landed (i.e., formed) on a step-shaped pad portion connected to the gate electrode in the connection region. However, as the number of layers of the gate electrode increases, there is a problem that an area occupied by the step-shaped pad portion increases. To solve this problem, instead of forming a step-shaped pad portion, a stair-free contact structure has been proposed in which a contact plug hole penetrating a gate electrode is formed and an insulating liner (i.e., an insulating spacer) is formed on the sidewall of the contact plug hole. However, in the process of a stair-free contact structure, there is a problem that the contact plug comes into contact with an uncorresponding gate electrode (i.e., becomes electrically connected to an incorrect gate electrode) due to a defect in which a protrusion occurs in a bottom etching process of the insulating spacer.

In the method of manufacturing the semiconductor device 100 according to embodiments of the inventive concepts, since the contact plug hole CH and the contact plug CP1 include smooth sidewalls without protrusions, the contact plug CP1 comes in contact with the contact surface 230C of the gate electrode 230 (i.e., becomes electrically connected to the correct gate electrode 230), and a problem in which the contact plug CP1 comes in contact with the uncorresponding gate electrode 230 (i.e., becomes electrically connected to an incorrect gate electrode 230) may be prevented. Therefore, the semiconductor device 100 may have excellent electrical characteristics and improved reliability.

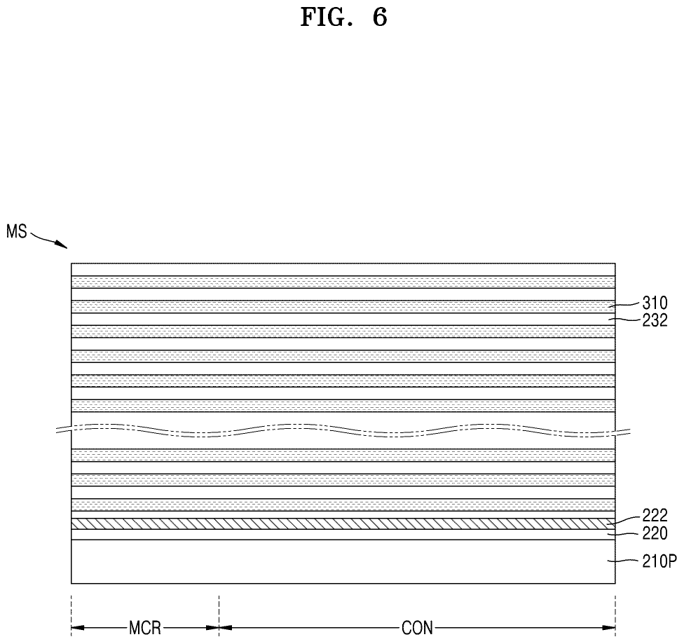

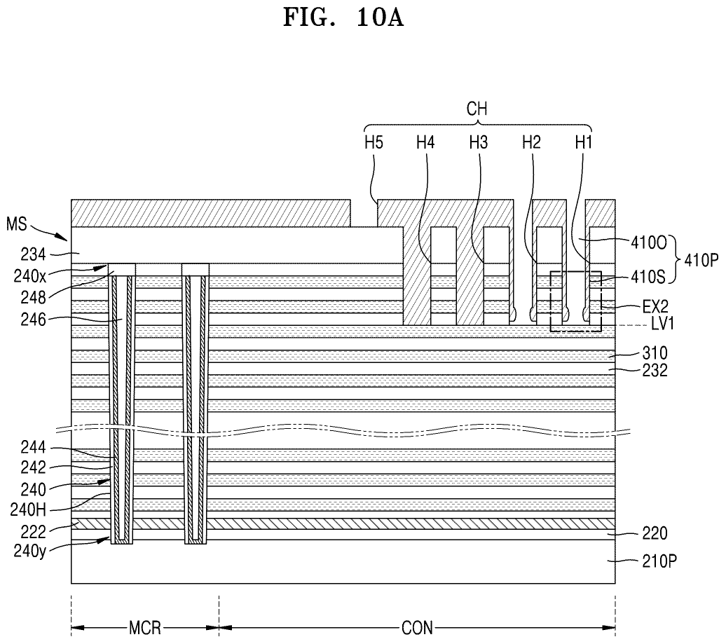

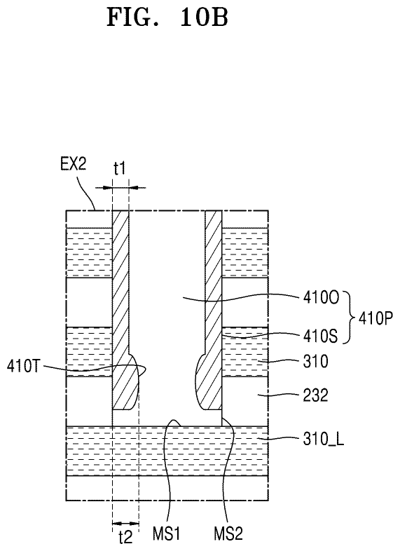

FIGS. 6 to 9, 10A, 10B, 11 to 16, 17A, 17B, 18, and 19 are cross-sectional views illustrating a method of manufacturing a semiconductor device 100 according to embodiments and are an enlarged view of a portion EX1 of FIG. 5. Further, FIG. 10B is an enlarged view of a portion EX2 of FIG. 10A, and FIG. 17B is an enlarged view of a portion EX3 of FIG. 17A.

Referring to FIG. 6, a buffer insulating layer 220 may be formed on a cell substrate 210P, and an etching stop layer 222 may be formed on the buffer insulating layer 220.

In embodiments, the cell substrate 210P may include at least one of silicon (Si), germanium (Ge), silicon germanium (SiGe), gallium arsenide (GaAs), indium gallium arsenide (InGaAs), aluminum gallium arsenide (AlGaAs), or a combination thereof. The buffer insulating layer 220 may be formed using silicon oxide. In embodiments, the etching stop layer 222 may be formed using polysilicon.

In embodiments, a mold stack MS may be formed by alternately forming sacrificial layers 310 and mold insulating layers 232 on the etching stop layer 222 in the cell region MCR and the connection region CON. In some embodiments, the sacrificial layers 310 and the mold insulating layers 232 may be formed using materials having etch selectivity with respect to each other. For example, the sacrificial layers 310 may include silicon nitride, and the mold insulating layers 232 may include silicon oxide.

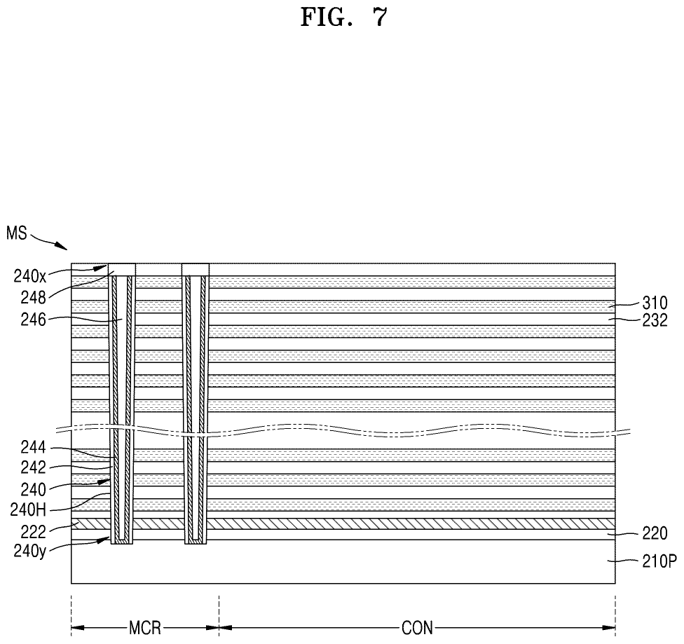

Referring to FIG. 7, a channel structure 240 that penetrates the mold stack MS and extends in the vertical direction Z may be formed in the cell region MCR. Although not specifically shown in FIG. 7, the vertical direction Z may be substantially perpendicular to a bottom surface of the cell substrate 210P.

In embodiments, in a process for forming the channel structure 240, a channel hole 240H penetrating the mold stack in the cell region MCR may be formed, a gate insulating layer 242, a channel layer 244, and a buried insulating layer 246 may be sequentially formed on an inner wall of the channel hole 240H, and a drain region 248 may be formed at an inlet (i.e., at an end) of the channel hole 240H.

In embodiments, the channel hole 240H may extend in the vertical direction Z through the mold stack MS, the etching stop layer 222, and the buffer insulating layer 220, and a top surface of the cell substrate 210P may be exposed at the bottom of the channel hole 240H.

The channel structure 240 has a first end 240x and a second end 240y opposite thereto, and the first end 240x may be adjacent to the top surface of the mold stack MS and/or may be arranged at the same vertical level as the top surface of the mold stack MS. As used herein, the term “vertical level” may refer to a height or distance in a vertical direction (e.g., the vertical direction Z) from a bottom surface of the cell substrate 210P. The second end 240y of the channel structure 240 may be arranged to be in contact with the top surface of the cell substrate 210P, and may be arranged at a lower vertical level than the top surface of the cell substrate 210P. In some embodiments, the width of the first end 240x of the channel structure 240 in the horizontal direction may be greater than the width of the second end 240y of the channel structure 240 in the horizontal direction.

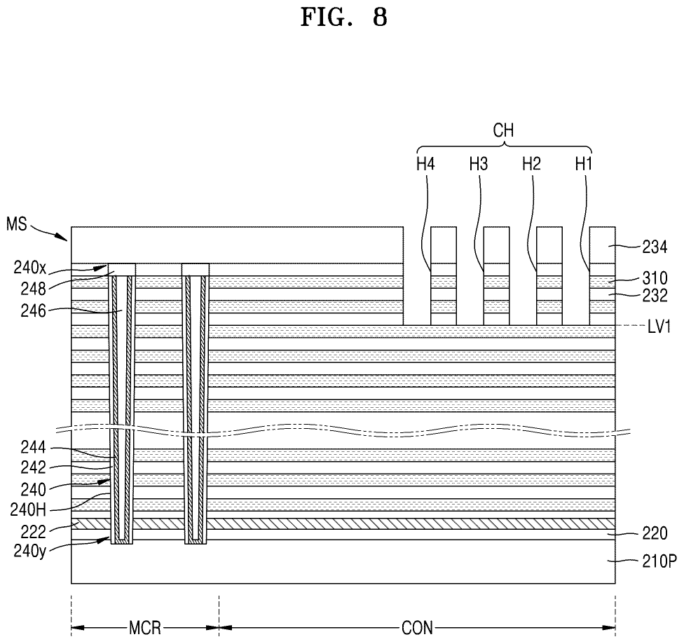

Referring to FIG. 8, a stack cover insulating layer 234 may be formed on the top surface of the mold stack MS. The stack cover insulating layer 234 may be on (e.g., may cover) the entire top surface of the mold stack MS in the cell region MCR and the connection region CON. The stack cover insulating layer 234 has flat top surface and bottom surface levels over the entire cell region MCR and the entire connection region CON, and may have a constant thickness over the entire cell region MCR and the entire connection region CON.

In this case, a stack isolation opening WLH (see FIGS. 4 and 5) extending in the vertical direction Z through the mold stack MS and the stack cover insulating layer 234 may be formed in the cell region MCR and the connection region CON. The stack isolation opening WLH may extend in the first horizontal direction X (see FIG. 4) in the cell region MCR and the connection region CON.

In some embodiments, a dummy channel hole extending in the vertical direction Z through the mold stack MS may be formed in the connection region CON. In some embodiments, the process for forming the dummy channel hole may be simultaneously performed in the etching process for forming the stack isolation opening WLH. In other embodiments, the process for forming the dummy channel hole may be performed simultaneously in the etching process for forming the channel structure 240.

A plurality of contact plug holes CH extending in the vertical direction Z may be formed by removing portions of the stack cover insulating layer 234 and the mold stack MS in the connection region CON. For example, the plurality of contact plug holes CH may include first to fourth holes H1 to H4. In this case, vertical levels of the first to fourth holes H1 to H4 may be the same. For example, bottom surfaces of the first to fourth holes H1 to H4 may have a first vertical level LV1. In other words, bottom surfaces of the first to fourth holes H1 to H4 may be spaced apart from a bottom surface of the mold stack MS by a first distance extending from the bottom surface of the mold stack MS to the first vertical level LV1. In embodiments, the plurality of contact plug holes CH may expose a top surface of a sacrificial layer 310.

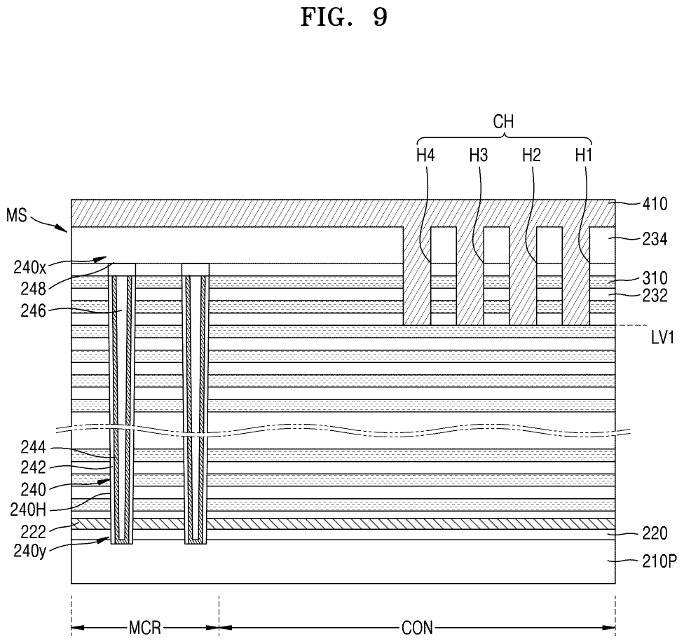

Referring to FIG. 9, a photoresist layer 410 may be formed on the stack cover insulating layer 234. The photoresist layer 410 may be formed to be on (e.g., to cover) the mold stack MS and the plurality of contact plug holes CH.

In embodiments, the photoresist layer 410 may be formed to be in (e.g., to fill) all of the plurality of contact plug holes CH. The vertical level of the bottom surface of the photoresist layer 410 may be the first vertical level LV1.

Referring to FIGS. 10A and 10B, a photoresist pattern 410P may be formed by patterning the photoresist layer 410 (see FIG. 9). The photoresist pattern 410P may be formed by removing a portion of the photoresist layer 410 on (e.g., covering) the plurality of contact plug holes CH.

In embodiments, the photoresist pattern 410P may include an opening 410O and a side photoresist pattern 410S. The opening 410O may be formed by removing a portion of the photoresist layer 410 in the contact plug holes CH in the vertical direction. The opening 410O may expose an upper surface of the mold stack MS. In this case, the upper surface of the mold stack MS exposed through the opening 410O may be referred to as a first exposed surface MS1.

In embodiments, an opening 410O may be formed in one or more contact plug holes CH selected from the plurality of contact plug holes CH. For example, FIG. 10A shows that the openings 410O are formed in the first hole H1, the second hole H2, and the fifth hole H5 among the plurality of contact plug holes CH. However, embodiments are not limited thereto. The photoresist layer 410 may remain in the contact plug holes CH in which the opening 410O is not formed. For example, the photoresist layer 410 may remain in the third hole H3 and the fourth hole H4.

In embodiments, the side photoresist pattern 410S may be formed in a process of forming the photoresist pattern 410P. The side photoresist pattern 410S may be formed on a sidewall (e.g., an inner sidewall) of the mold stack MS. The side photoresist pattern 410S may be formed during a process of exposing a contact plug hole CH to which a bottom anti-reflection coating (BARC) is not applied during the process of forming the photoresist pattern 410P. That is, the side photoresist pattern 410S may be formed in ones of the contact plug holes CH extending in the mold stack MS. For example, the side photoresist pattern 410S may be formed on the sidewall of the first hole H1 and the sidewall of the second hole H2, but may not be formed on the sidewall of the fifth hole H5.

In embodiments, the side photoresist pattern 410S may be arranged to be spaced apart by a predetermined distance from the first exposed surface MS1 of the mold stack MS exposed through the opening 410O. Accordingly, the opening 410O may expose a portion of the sidewall (e.g., the inner sidewall) of the mold stack MS. In this case, the sidewall of the mold stack MS exposed through the opening 410O may be referred to as a second exposed surface MS2. For example, the side photoresist pattern 410S may be formed such that an upper surface of the mold stack MS (i.e., the first exposed surface MS1) and a portion of a sidewall of the mold stack MS (i.e., the second exposed surface MS2) are exposed.

In embodiments, the side photoresist pattern 410S is formed on the sidewall of the mold stack MS, and may expose the second exposed surface MS2. The side photoresist pattern 410S may be arranged to be spaced apart by a predetermined distance from a sacrificial layer 310_L arranged at the lower end of the opening 410O. For example, a top surface of the sacrificial layer 310_L arranged at the lower end of the opening 410O may include the first exposed surface MS1. The side photoresist pattern 410S may be on (e.g., may cover) only a portion of the sidewall of the mold insulating layer 232 arranged at the lower end of the opening 410O. The sidewall of the mold insulating layer 232 arranged at the lower end of the opening 410O may include the second exposed surface MS2, and the second exposed surface MS2 may be exposed through the opening 410O.

In embodiments, the side photoresist pattern 410S may have a ring-shaped horizontal cross section. In other words, the side photoresist pattern 410S may have a ring shape when viewed in a plan view (i.e., when viewed from above). The side photoresist pattern 410S may be formed to have a first thickness t1 in the horizontal direction. In this case, the first thickness t1 may be greater than or equal to 2 micrometers (um). In other words, the side photoresist pattern 410S may include a first portion having the first thickness t1. As used herein, the first thickness t1 may also be referred to as a first width t1. For example, the horizontal direction may be substantially parallel to the bottom surface of the cell substrate 210P.

In embodiments, the side photoresist pattern 410S may further include a protrusion portion 410T. The protrusion portion 410T may be formed near (i.e., adjacent) the first exposed surface MS1. The protrusion portion 410T may also be formed near the second exposed surface MS2. The protrusion portion 410T may have a second thickness t2 in the horizontal direction greater than the first thickness t1. As used herein, the second thickness t2 may also be referred to as a second width t2. As the distance from the protrusion portion 410T in the vertical direction increases, the thickness (i.e., width) of the side photoresist pattern 410S decreases, and as a result, the protrusion portion 410T may be adjacent to the first portion of the side photoresist pattern 410S having the first thickness t1. For example, the first portion of the side photoresist pattern 410S having the first thickness t1 may be on the protrusion portion 410T of the side photoresist pattern 410S having the second thickness t2. In other embodiments, the side photoresist pattern 410S may not include the protrusion portion 410T and may be formed to have a conformal thickness (e.g., a substantially uniform thickness).

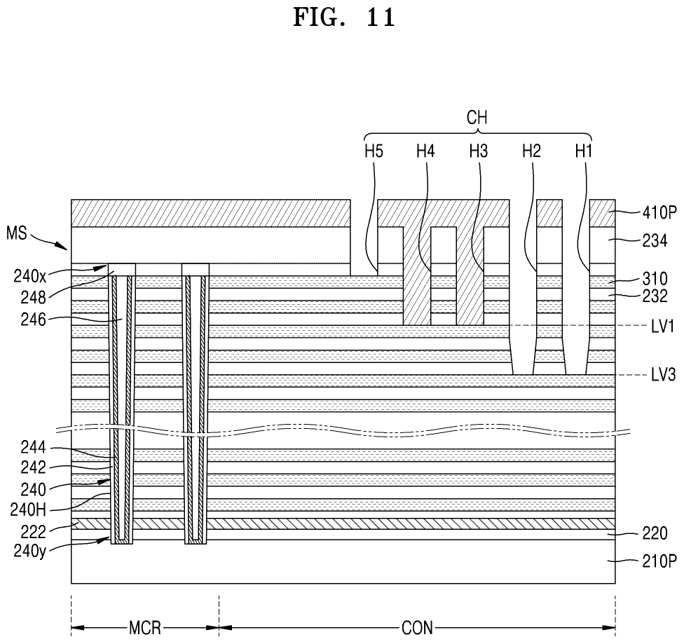

Referring to FIG. 11, ones of the plurality of contact plug holes CH may be extended in the vertical direction by etching the mold stack MS using a photoresist pattern 410P. In the process of extending the plurality of contact plug holes CH in the vertical direction, the side photoresist pattern 410S may be removed together with a portion of the mold stack MS. In other embodiments, the side photoresist pattern 410S may not be completely removed and a portion of the side photoresist pattern 410S may remain. For example, in the process of extending the plurality of contact plug holes CH in the vertical direction, a width of at least a portion of ones of the plurality of contact plug holes CH may be narrowed.

In embodiments, the plurality of contact plug holes CH may have different vertical levels. The first hole H1 and the second hole H2 exposed through the opening 410O (refer to FIG. 10A) may have a different vertical level from the third hole H3 and the fourth hole H4 that were not exposed through the opening 410O. For example, bottom surfaces of the first hole H1 and the second hole H2 may be closer to the bottom surface of the mold stack MS than bottom surfaces of the third hole H3 and the fourth hole H4 are. For example, the bottom surfaces of the first hole H1 and the second hole H2 may have a third vertical level LV3. In other words, the bottom surfaces of the first hole H1 and the second hole H2 may be spaced apart from the bottom surface of the mold stack MS by a third distance extending from the bottom surface of the mold stack MS to the third vertical level LV3. The third distance may be shorter than a first distance between the bottom surface of the mold stack MS and the first vertical level LV1. In addition, the fifth hole H5 exposed through the opening 410O may have a different vertical level than the third hole H3 and the fourth hole H4 that were not exposed through the opening 410O. In this case, the plurality of contact plug holes CH may expose top surfaces of ones of the sacrificial layers 310.

In embodiments, the first hole H1 and the second hole H2 may have a shape in which a width in the horizontal direction decreases toward the mold stack MS (e.g., toward the bottom surface of the mold stack MS). Each of the first hole H1 and the second hole H2 in which the side photoresist pattern 410S (refer to FIG. 10A) was formed may have a shape in which a width in a horizontal direction decreases toward the mold stack MS in the etching process. A width of the fifth hole H5 in the horizontal direction in which the side photoresist pattern 410S was not formed may be constant. In other embodiments, the first hole H1 and the second hole H2 may be formed to have a rounded curved sidewall toward the mold stack MS (e.g., toward the bottom surface of the mold stack MS).

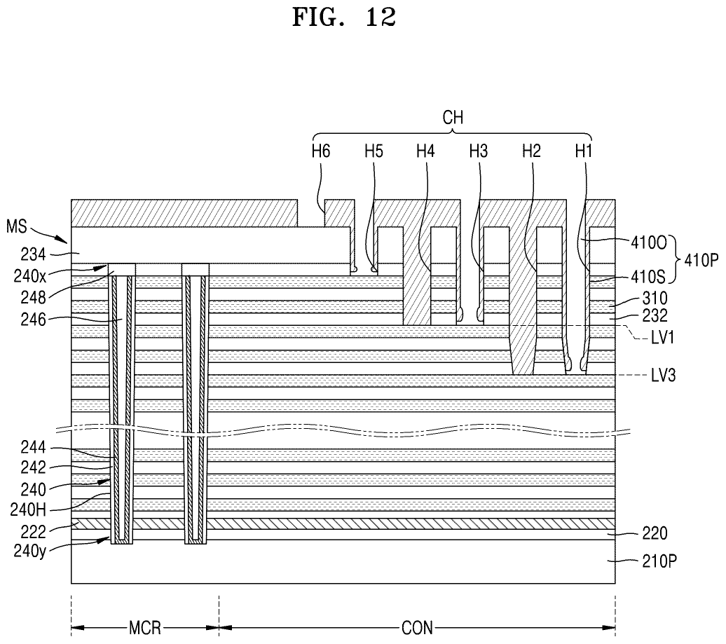

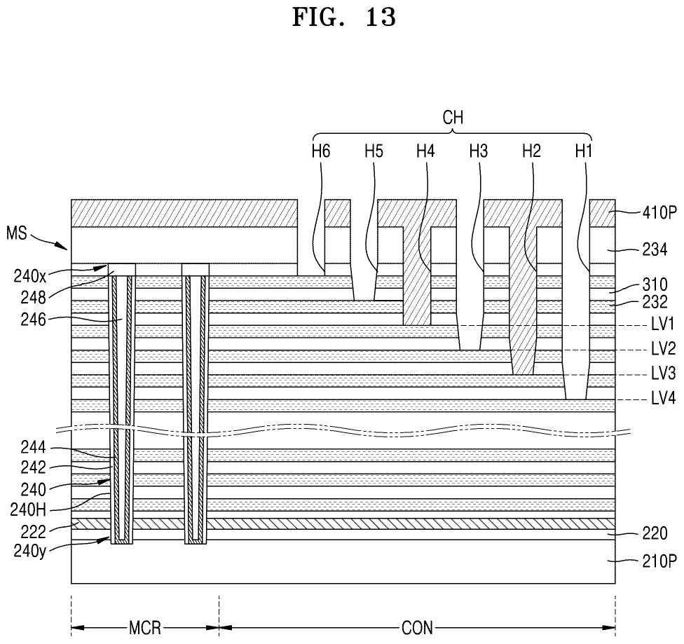

Referring to FIGS. 12 and 13, the process of FIGS. 9, 10A, 10B, and 11 may be repeatedly carried out. The operation of forming the photoresist layer 410 (refer to FIG. 9), the operation of forming the photoresist pattern 410P (refer to FIGS. 10A and 10B), and the operation of extending ones of the plurality of contact plug holes CH in the vertical direction (refer to FIG. 11) may be repeatedly performed.

The photoresist layer 410 (refer to FIG. 9) may be formed to be on (e.g., to cover) the mold stack MS and the plurality of contact plug holes CH, and the photoresist layer 410 may be patterned to form the photoresist pattern 410P. The photoresist pattern 410P may be formed by removing a portion of the photoresist layer 410 on (e.g., covering) the plurality of contact plug holes CH.

In embodiments, an opening 410O may be formed in one or more contact plug holes CH selected from the plurality of contact plug holes CH. For example, the openings 410O may be formed in the first hole H1, third hole H3, fifth hole H5, and sixth hole H6 among the plurality of contact plug holes CH. The photoresist layer 410 may remain in the contact plug hole CH in which the opening 410O is not formed. For example, the photoresist layer 410 may remain in the second hole H2 and the fourth hole H4.

In embodiments, the side photoresist pattern 410S may be formed in a process of forming the photoresist pattern 410P. The side photoresist pattern 410S may be formed on a sidewall (e.g., an inner sidewall) of the mold stack MS. For example, the side photoresist pattern 410S may be formed on the sidewall of the first hole H1, the sidewall of the third hole H3, and the sidewall of the fifth hole H5, but may not be formed on the sidewall of the sixth hole H6.

In embodiments, ones of the plurality of contact plug holes CH may be extended in a vertical direction by etching the mold stack MS using the photoresist pattern 410P. In the process of extending the plurality of contact plug holes CH in the vertical direction, the side photoresist pattern 410S may be removed together with a portion of the mold stack MS. For example, in the process of extending the plurality of contact plug holes CH in the vertical direction, a width of at least a portion of ones of the plurality of contact plug holes CH may be narrowed. The first hole H1, the third hole H3, and the fifth hole H5 exposed through the openings 410O, respectively, may extend in the vertical direction.

The plurality of contact plug holes CH may have heights varying in the vertical direction. The plurality of contact plug holes CH may have different heights to expose a top surface of a corresponding sacrificial layer 310 among the plurality of sacrificial layers 310. Vertical levels of the top surfaces of the sacrificial layers 310 exposed by the plurality of contact plug holes CH may be different from each other.

In embodiments, the plurality of contact plug holes CH may have different vertical levels. For example, the bottom surface of the fourth hole H4 may have a first vertical level LV1, the bottom surface of the third hole H3 may have a second vertical level LV2, the bottom surface of the second hole H2 may have a third vertical level LV3, and the bottom surface of the first hole H1 may have a fourth vertical level LV4. For example, a first distance between the bottom surface of the mold stack MS and the first vertical level LV1, a second distance between the bottom surface of the mold stack MS and the second vertical level LV2, a third distance between the bottom surface of the mold stack MS and the third vertical level LV3, and a fourth distance between the bottom surface of the mold stack MS and the fourth vertical level LV4 may be different from each other.

In embodiments, the first hole H1, the third hole H3, and the fifth hole H5 may have a shape in which a width in the horizontal direction decreases toward the mold stack MS (e.g., toward the bottom surface of the mold stack MS). Each of the first hole H1, the third hole H3, and the fifth hole H5 in which the side photoresist pattern 410S was formed may have a shape in which a width in the horizontal direction decreases toward the mold stack MS during the etching process. A width of the sixth hole H6 in the horizontal direction in which the side photoresist pattern 410S was not formed may be constant.

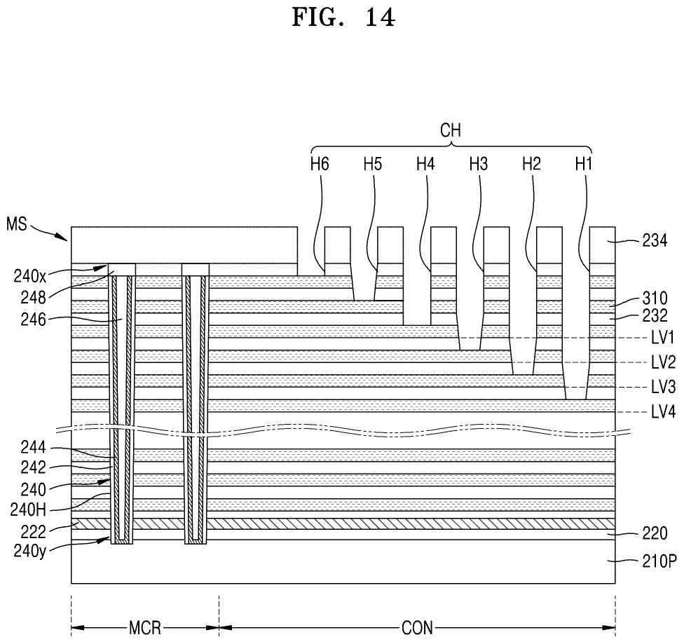

Referring to FIG. 14, a remaining photoresist pattern 410P (see FIG. 13) may be removed. As the photoresist pattern 410P is removed, the mold stack MS and the stack cover insulating layer 234 may be exposed.

By repeatedly performing several photo processes as described above, the method of manufacturing the semiconductor device 100 according to embodiments of the present disclosure may form a stair-free contact structure that does not form a step-shaped pad portion connected to the gate electrode 230 (e.g., see FIG. 5).

In general, a contact plug is landed (i.e., formed) on a step-shaped pad portion connected to the gate electrode in the connection region. However, as the number of layers of the gate electrode increases, there is a problem that an area occupied by the step-shaped pad portion increases. To solve this problem, instead of forming a step-shaped pad portion, a stair-free contact structure has been proposed in which a contact plug hole penetrating a gate electrode is formed and an insulating liner (i.e., insulating spacer) is formed on the sidewall of the contact plug hole. However, in the process of a stair-free contact structure, there is a problem that the contact plug comes into contact with an uncorresponding gate electrode (i.e., becomes electrically connected to an incorrect gate electrode) due to a defect in which a protrusion occurs in a bottom etching process of the insulating spacer.

In the method of manufacturing the semiconductor device 100 according to embodiments of the inventive concepts, since the contact plug hole CH and the contact plug CP1 to be formed therein include smooth sidewalls without protrusions, the contact plug CP1 comes in contact with the contact surface 230C of the gate electrode 230 (i.e., becomes electrically connected to the correct gate electrode 230), and a problem in which the contact plug CP1 comes in contact with the uncorresponding gate electrode 230 (i.e., becomes electrically connected to an incorrect gate electrode 230) may be prevented. Therefore, the semiconductor device 100 may have excellent electrical characteristics and improved reliability.

In addition, the method of manufacturing the semiconductor device 100 according to embodiments of the present disclosure may control a bowing phenomenon of the plurality of contact plug holes CH in the process by forming the side photoresist pattern 410S on the sidewall of the mold stack MS in the process of forming the plurality of contact plug holes CH. Therefore, process stability of the semiconductor device 100 may increase and process cost (i.e., manufacturing costs) may be reduced.

In addition, the size of the contact plug hole CH may be adjusted by adjusting the thickness t1 (see FIG. 10B) of the side photoresist pattern 410S. Therefore, an area occupied by the connection region CON in the semiconductor device 100 may be minimized.

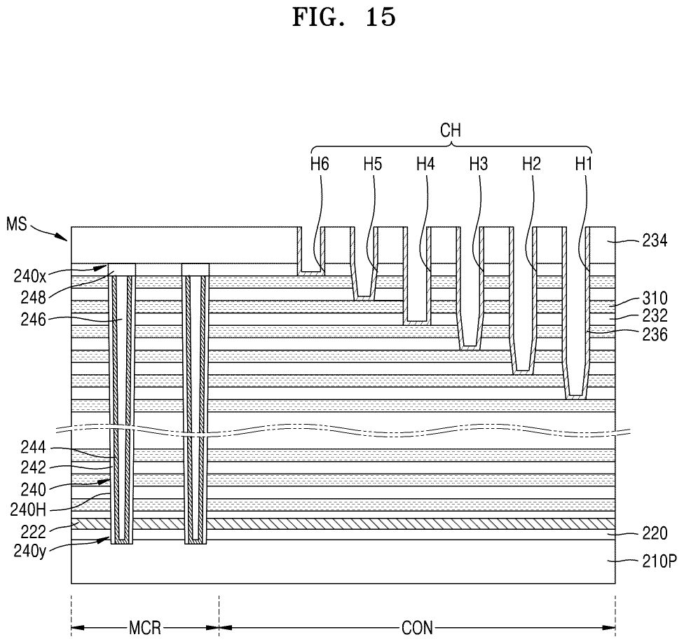

Referring to FIG. 15, the insulating spacers 236 on (e.g., covering) the plurality of contact plug holes CH may be formed. The insulating spacers 236 may be formed in the plurality of contact plug holes CH. In embodiments, the insulating spacers 236 may conformally be on (e.g., may conformally cover) the upper surfaces and sidewalls of the exposed mold stack MS.

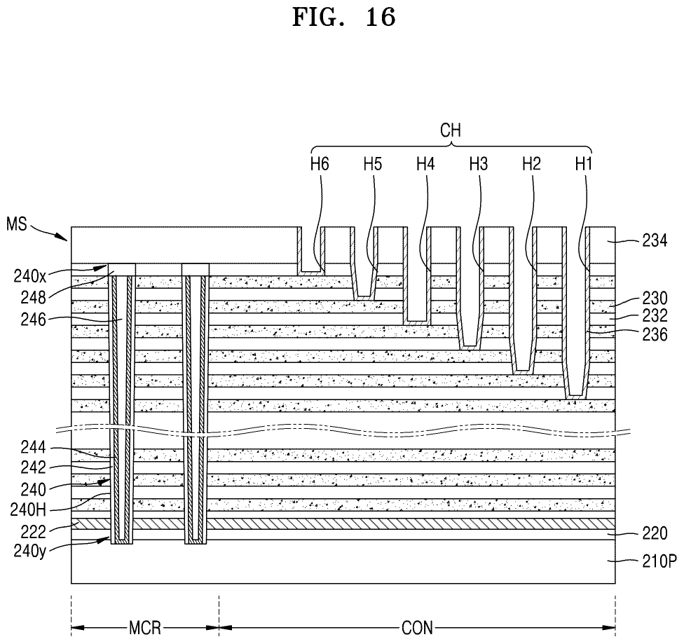

Referring to FIG. 16, the sacrificial layers 310 (refer to FIG. 15) may be removed, and gate electrodes 230 may be formed using a metal material in a space in which the sacrificial layers 310 are removed. In other words, the sacrificial layers 310 may be replaced with the gate electrodes 230. The thickness of each of the plurality of gate electrodes 230 in the vertical direction may be substantially the same as the thickness of each of the sacrificial layers 310. As the plurality of sacrificial layers 310 are replaced with the plurality of gate electrodes 230, the plurality of gate electrodes 230 may extend in the horizontal direction on the cell region MCR and the connection region CON. The plurality of gate electrodes 230 may overlap each other in a vertical direction on the connection region CON. For example, the plurality of gate electrodes 230 arranged at different vertical levels on the connection region CON may have the same width in the horizontal direction.

Referring to FIGS. 17A and 17B, an etch-back process may be performed on the bottom of the plurality of contact plug holes CH to remove a portion of the insulating spacer 236 arranged at the bottom of each contact plug hole CH and expose the top surface of a respective gate electrode 230.

For example, a portion of the insulating spacer 236 in each contact plug hole CH and on the top surface of the respective gate electrode 230 may be removed by the etch-back process, and the top surface of the respective gate electrode 230 may be exposed. The top surface of the exposed gate electrode 230 may be referred to as the gate contact surface 230C.

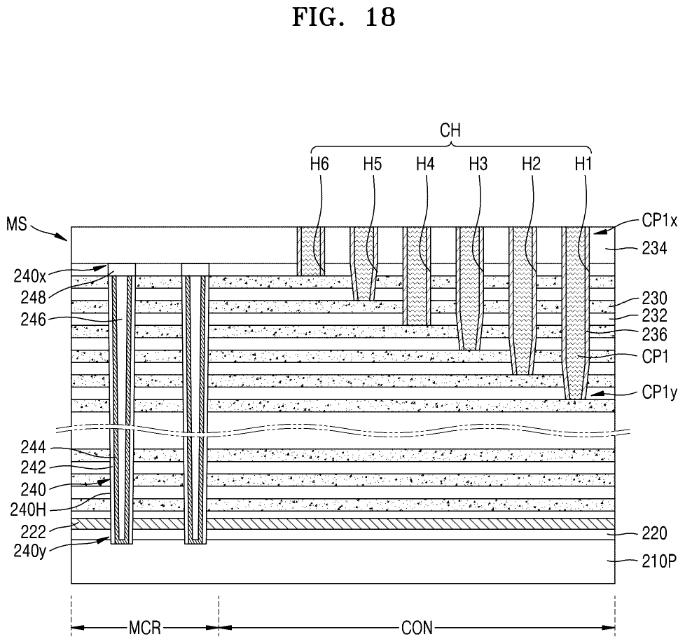

Referring to FIG. 18, the plurality of contact plugs CP1 may respectively be formed in the plurality of contact plug holes CH. Side surfaces of the plurality of contact plugs CP1 may be in contact with sidewalls of the plurality of insulating spacers 236.

In embodiments, the contact plug CP1 has a first end CP1x and a second end CP1y, the first end CP1x of the contact plug CP1 may be arranged at the same vertical level as a top surface of the stack cover insulating layer 234, and the second end CP1y may be placed on each corresponding gate contact surface 230C (see FIG. 17B).

In embodiments, a bottom surface of each of the plurality of contact plugs CP1 may be in contact with a gate contact surface 230C, and accordingly, one contact plug CP1 may be electrically connected to the corresponding gate electrode 230 through the gate contact surface 230C.

For example, the bottom surface of one contact plug CP1 may be electrically connected to the corresponding gate electrode 230, while the sidewall of one contact plug CP1 may not be electrically connected to the gate electrode(s) 230 arranged at a higher vertical level than the corresponding gate electrode 230. An insulating spacer 236 may be arranged between the gate electrode(s) 230 arranged at a vertical level higher than the corresponding gate electrode 230 and the sidewall of the one contact plug CP1, and accordingly, the gate electrode(s) 230 arranged at a vertical level higher than the corresponding gate electrode 230 and the sidewall of the one contact plug CP1 may be insulated from each other.

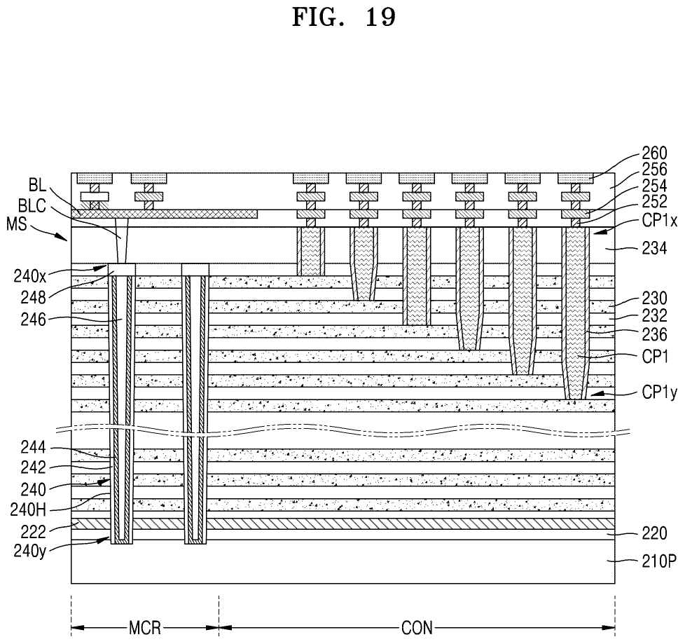

Referring to FIG. 19, a bit line contact BLC and a bit line BL electrically connected to a channel structure 240 may be formed. A connection via 252 and a connection wiring layer 254 electrically connected to the bit line BL and the contact plug CP1 may be formed. An interlayer insulating layer 256 may be formed on the connection via 252 and the connection wiring layer 254. A connection pad 260 may be formed on a top surface of the interlayer insulating layer 256.

Referring back to FIG. 5, the peripheral circuit structure PS may be prepared. The peripheral circuit transistor 120TR is formed on the substrate 110 in which the active region AC is defined by the device isolation layer 112, the plurality of peripheral circuit contacts 132 and the plurality of peripheral circuit wiring layers 134 electrically connected to the plurality of peripheral circuit transistors 120TR and the substrate 110 are formed on the substrate 110, and then the interlayer insulating layer 130 on (e.g., covering) the plurality of peripheral circuit transistors 120TR, the plurality of peripheral circuit contacts 132, and the plurality of peripheral circuit wiring layers 134 may be formed on the substrate 110. The connection pad 260 may be formed on a top surface of the interlayer insulating layer 130.

Thereafter, the peripheral circuit structure PS may be attached to the cell structure CS. The peripheral circuit structure PS and the cell structure CS may be attached through the connection pad 260 and the interlayer insulating layers 130 and 256 in a metal-oxide hybrid bonding method, but are not limited thereto. Thereafter, the structure to which the peripheral circuit structure PS and the cell structure CS are attached may be reversed so that the substrate 110 faces upward.

Thereafter, the cell substrate 210P (see FIG. 19) may be removed. The cell substrate 210P may be removed by a grinding process and a subsequent etching process, and a buffer insulating layer 220 (see FIG. 19) may be exposed. The buffer insulating layer 220 may also be removed and a top surface of the etching stop layer 222 may be exposed. As the buffer insulating layer 220 is removed, the second end 240y of the channel structure 240 may protrude toward (e.g., above) the top surface of the etching stop layer 222. As the cell substrate 210P and the buffer insulating layer 220 are removed, the upper side of the stack isolation insulating layer WLI may also be exposed to protrude above the etching stop layer 222.

Thereafter, the top surface of the channel layer 244 may be exposed by removing a portion of the gate insulating layer 242 exposed to the second end 240y of the channel structure 240. In some embodiments, the top surface of the gate insulating layer 242 may be arranged in the same plane as (i.e., may be coplanar with) the top surface of the channel layer 244.

In other embodiments, a process of removing the gate insulating layer 242 may be performed until the top surface of the etching stop layer 222 is exposed. In some embodiments, the gate insulating layer 242 may be arranged at a level lower than the top surface of the channel layer 244 and the upper side of the gate insulating layer 242 may be removed so that the top surface and a portion of the sidewall of the channel layer 244 are exposed.

Thereafter, a common source layer 210 may be formed in the cell region MCR, the connection region CON, and the peripheral circuit connection region PCR. The common source layer 210 may be formed using polysilicon. For example, the common source layer 210 may be formed using polysilicon doped with n-type impurities. In the cell region MCR, the common source layer 210 may be conformally formed on the exposed top surfaces of the etching stop layer 222 and the channel layer 244. In this case, the portion of the common source layer 210 and the portion of the etching stop layer 222 arranged in the connection region CON and the peripheral circuit connection region PRC may be removed.

Thereafter, an upper insulating layer 272 may be formed on the common source layer 210 and the uppermost mold insulating layer 232 in the cell region MCR, the connection region CON, and the peripheral circuit connection region PCR.

Thereafter, a mask pattern may be formed on the upper insulating layer 272, and a rear contact hole may be formed by removing a portion of the upper insulating layer 272 using the mask pattern as an etching mask. A common source contact 274 may be formed in the rear contact hole, and a rear wiring layer 276 electrically connected to the common source contact 274 may be formed on the upper insulating layer 272.

Thereafter, a passivation layer 278 on (e.g., covering) the rear wiring layer 276 may be formed on the upper insulating layer 272, and an opening OP may be formed in the passivation layer 278 to expose the top surface of the rear wiring layer 276. The semiconductor device 100 may be formed by performing the processes described above.

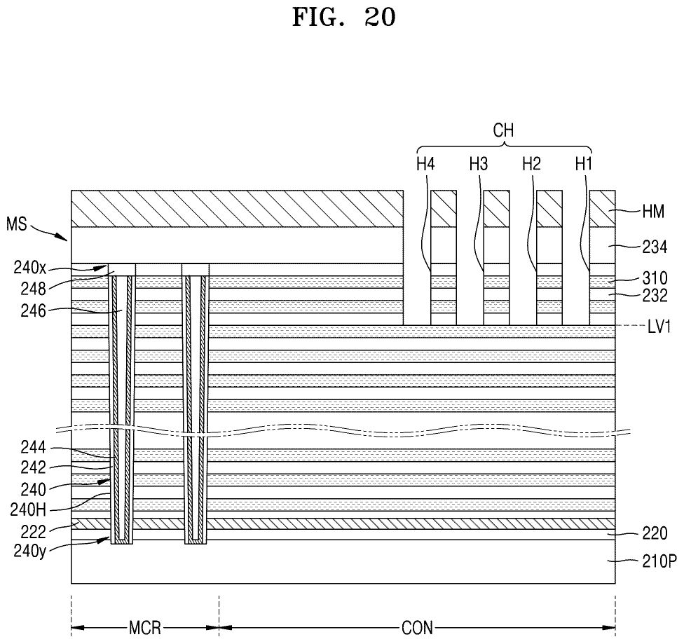

FIGS. 20 to 26 are cross-sectional views illustrating a method of manufacturing a semiconductor device 100 according to embodiments and are an enlarged view of the portion EX1 of FIG. 5. In FIGS. 20 to 26, the same reference numerals as in FIGS. 5 to 19 indicate the same components. In addition, the description of the portions common to the portions described with reference to FIGS. 5 to 19 may be omitted.

Referring to FIG. 20, a stack cover insulating layer 234 and a hard mask HM may be sequentially formed on the top surface of the mold stack MS. The stack cover insulating layer 234 and the hard mask HM may be on (e.g., may cover) the entire top surface of the mold stack MS in the cell region MCR and the connection region CON. The hard mask HM may include silicon oxide, silicon oxynitride, silicon nitride, TEOS, amorphous silicon, polycrystalline silicon, high-k dielectric materials, or a combination thereof.

The plurality of contact plug holes CH extending in the vertical direction Z may be formed by removing portions of the stack cover insulating layer 234, the hard mask HM, and the mold stack MS in the connection region CON. For example, the plurality of contact plug holes CH may include first to fourth holes H1 to H4. In this case, vertical levels of the first to fourth holes H1 to H4 may be the same. For example, bottom surfaces of the first to fourth holes H1 to H4 may have a first vertical level LV1. In other words, bottom surfaces of the first to fourth holes H1 to H4 may be spaced apart from a bottom surface of the mold stack MS by a first distance extending from the bottom surface of the mold stack MS to the first vertical level LV1.

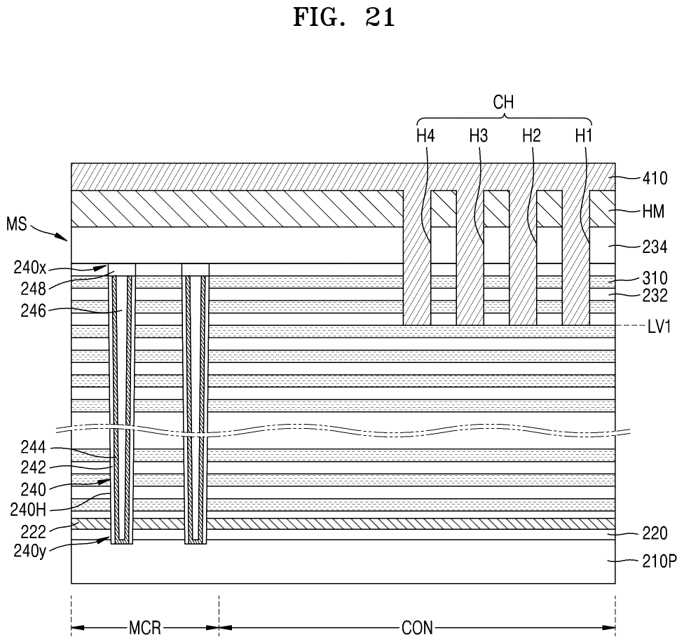

Referring to FIG. 21, a photoresist layer 410 may be formed on the hard mask HM. The photoresist layer 410 may be formed to be on (e.g., to cover) the mold stack MS and the plurality of contact plug holes CH.

In embodiments, the photoresist layer 410 may be formed to be in (e.g., to fill) all of the plurality of contact plug holes CH. The vertical level of the bottom surface of the photoresist layer 410 may be the first vertical level LV1.

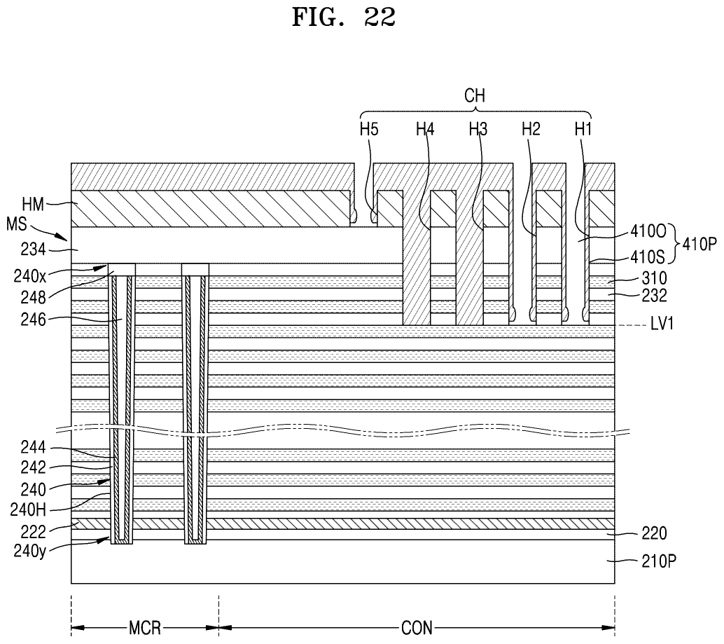

Referring to FIG. 22, a photoresist pattern 410P may be formed by patterning the photoresist layer 410 (see FIG. 21). The photoresist pattern 410P may be formed by removing a portion of the photoresist layer 410 on (e.g., covering) the plurality of contact plug holes CH.

In embodiments, the photoresist pattern 410P may include an opening 410O and a side photoresist pattern 410S. The opening 410O may be formed by removing a portion of the photoresist layer 410 in the contact plug holes CH in the vertical direction. The opening 410O may expose an upper surface of the mold stack MS. In this case, the upper surface of the mold stack MS exposed through the opening 410O may be referred to as a first exposed surface MS1 (see FIG. 10B).

In embodiments, an opening 410O may be formed in one or more contact plug holes CH selected from the plurality of contact plug holes CH. For example, FIG. 22 shows that the openings 410O are formed in the first hole H1, the second hole H2, and the fifth hole H5 among the plurality of contact plug holes CH. However, embodiments are not limited thereto. The photoresist layer 410 may remain in the contact plug hole CH in which the opening 410O is not formed. For example, the photoresist layer 410 may remain in the third hole H3 and the fourth hole H4.

In embodiments, the side photoresist pattern 410S may be formed in a process of forming the photoresist pattern 410P. The side photoresist patterns 410S may be formed on the sidewall of the mold stack MS and the sidewall of the hard mask HM. For example, the side photoresist pattern 410S may be formed on a sidewall of the first hole H1, a sidewall of the second hole H2, and a sidewall of the fifth hole H5.

In embodiments, the side photoresist pattern 410S may be arranged to be spaced apart by a predetermined distance from the first exposed surface MS1 of the mold stack MS exposed through the opening 410O. Accordingly, the opening 410O may expose a portion of the sidewall of the mold stack MS. In this case, the sidewall of the mold stack MS exposed through the opening 410O may be referred to as the second exposed surface MS2 (see FIG. 10B). For example, the side photoresist pattern 410S may be formed such that an upper surface of the mold stack MS (i.e., the first exposed surface MS1) and a portion of a sidewall of the mold stack MS (i.e., the second exposed surface MS2) are exposed.

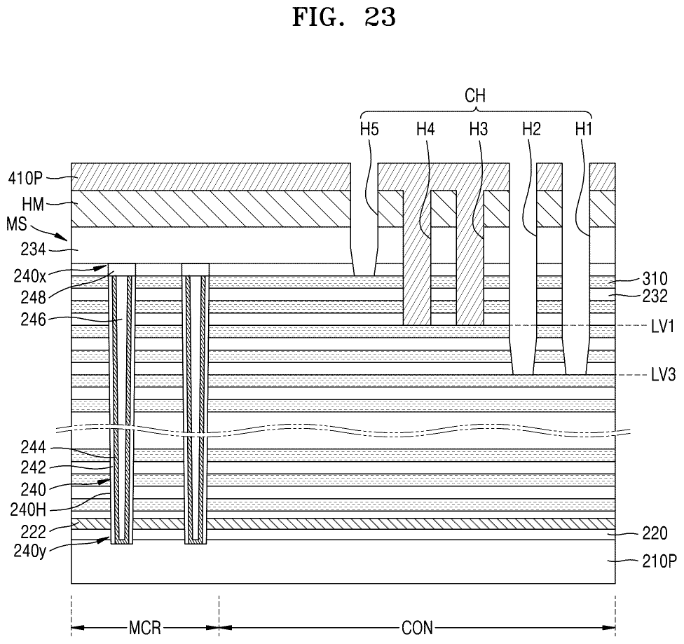

Referring to FIG. 23, ones of the plurality of contact plug holes CH may be extended in the vertical direction by etching the mold stack MS using the photoresist pattern 410P. In the process of extending the plurality of contact plug holes CH in the vertical direction, the side photoresist pattern 410S may be removed together with a portion of the mold stack MS. In other embodiments, the side photoresist pattern 410S may not be completely removed and a portion of the side photoresist pattern 410S may remain. For example, in the process of extending the plurality of contact plug holes CH in the vertical direction, a width of at least a portion of ones of the plurality of contact plug holes CH may be narrowed.

In embodiments, the plurality of contact plug holes CH may have different vertical levels. For example, the bottom surfaces of the first hole H1 and the second hole H2 may have a third vertical level LV3. In other words, the bottom surfaces of the first hole H1 and the second hole H2 may be spaced apart from the bottom surface of the mold stack MS by a third distance extending from the bottom surface of the mold stack MS to the third vertical level LV3. The third distance may be shorter than a first distance between the bottom surface of the mold stack MS and the first vertical level LV1.

In embodiments, the first hole H1 and the second hole H2 may have a shape in which a width in the horizontal direction decreases toward the mold stack MS (e.g., toward the bottom surface of the mold stack MS). Each of the first hole H1, the second hole H2, and the fifth hole H5 in which the side photoresist pattern 410S (see FIG. 22) was formed may have a shape in which a width in the horizontal direction decreases toward the mold stack MS during the etching process.

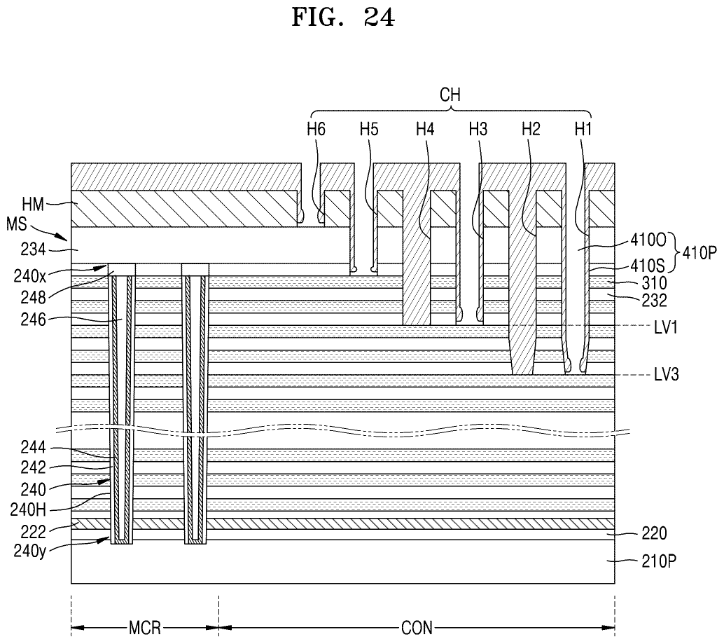

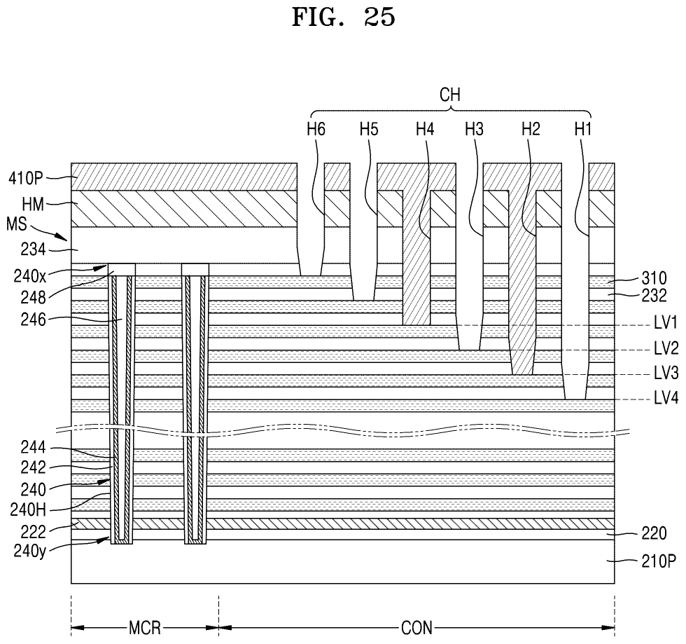

Referring to FIGS. 24 and 25, the process of FIGS. 21, 22, and 23 may be repeatedly carried out. The operation of forming the photoresist layer 410 (refer to FIG. 21), the operation of forming the photoresist pattern 410P (refer to FIG. 22), and the operation of extending ones of the plurality of contact plug holes CH in the vertical direction (refer to FIG. 23) may be repeatedly performed.

The photoresist layer 410 (refer to FIG. 21) may be formed to be on (e.g., to cover) the mold stack MS, the hard mask HM, and the plurality of contact plug holes CH, and the photoresist layer 410 may be patterned to form the photoresist pattern 410P. The photoresist pattern 410P may be formed by removing a portion of the photoresist layer 410 on (e.g., covering) the plurality of contact plug holes CH.

In embodiments, an opening 410O may be formed in one or more contact plug holes CH selected from the plurality of contact plug holes CH. For example, the openings 410O may be formed in the first hole H1, third hole H3, fifth hole H5, and sixth hole H6 among the plurality of contact plug holes CH. The photoresist layer 410 may remain in the contact plug hole CH in which the opening 410O is not formed. For example, the photoresist layer 410 may remain in the second hole H2 and the fourth hole H4.

In embodiments, the side photoresist pattern 410S may be formed in a process of forming the photoresist pattern 410P. The side photoresist pattern 410S may be formed on sidewalls of the mold stack MS and the hard mask HM. For example, the side photoresist pattern 410S may be formed on a sidewall of the first hole H1, a sidewall of the third hole H3, a sidewall of the fifth hole H5, and a sidewall of the sixth hole H6.

In embodiments, ones of the plurality of contact plug holes CH may be extended in a vertical direction by etching the mold stack MS using the photoresist pattern 410P. In the process of extending the plurality of contact plug holes CH in the vertical direction, the side photoresist pattern 410S may be removed together with a portion of the mold stack MS. For example, in the process of extending the plurality of contact plug holes CH in the vertical direction, a width of at least a portion of ones of the plurality of contact plug holes CH may be narrowed. The first hole H1, the third hole H3, the fifth hole H5, and the sixth hole H6 exposed through the openings 410O may extend in the vertical direction.

The plurality of contact plugs CH may have heights varying in the vertical direction. The plurality of contact plug holes CH may have different heights to expose a top surface of a corresponding sacrificial layer 310 among the plurality of sacrificial layers 310. Vertical levels of the top surfaces of the sacrificial layers 310 exposed by the plurality of contact plug holes CH may be different from each other.

In embodiments, the plurality of contact plug holes CH may have different vertical levels. For example, the bottom surface of the fourth hole H4 may have a first vertical level LV1, the bottom surface of the third hole H3 may have a second vertical level LV2, the bottom surface of the second hole H2 may have a third vertical level LV3, and the bottom surface of the first hole H1 may have a fourth vertical level LV4. For example, a first distance between the bottom surface of the mold stack MS and the first vertical level LV1, a second distance between the bottom surface of the mold stack MS and the second vertical level LV2, a third distance between the bottom surface of the mold stack MS and the third vertical level LV3, and a fourth distance between the bottom surface of the mold stack MS and the fourth vertical level LV4 may be different from each other.

In embodiments, each of the first hole H1, the third hole H3, the fifth hole H5, and the sixth hole H6 may have a shape in which a width in the horizontal direction decreases toward the mold stack MS (e.g., toward the bottom surface of the mold stack MS). Each of the first hole H1, the third hole H3, the fifth hole H5, and the sixth hole H6 in which the side photoresist pattern 410S was formed may have a shape in which a width in the horizontal direction decreases toward the mold stack MS during the etching process.

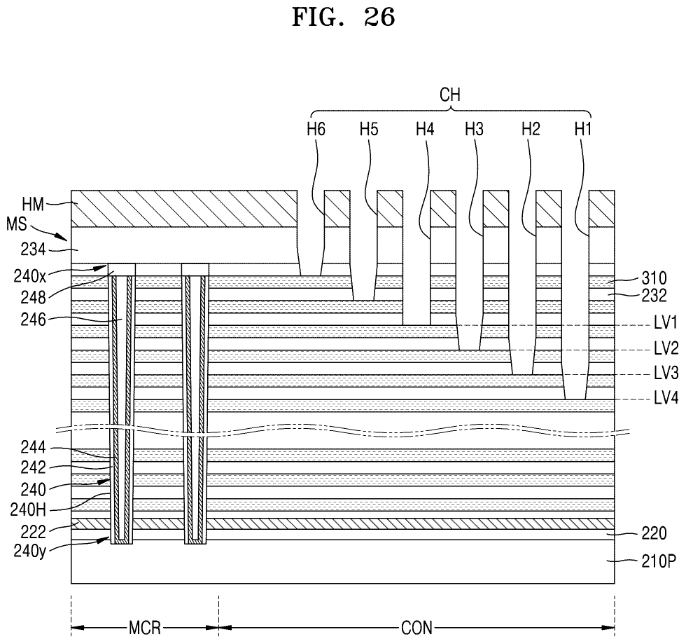

Referring to FIG. 26, a remaining photoresist pattern 410P (see FIG. 25) may be removed. As the photoresist pattern 410P is removed, the mold stack MS, the hard mask HM, and the stack cover insulating layer 234 may be exposed. Thereafter, the semiconductor device 100 may be manufactured by performing the processes of FIGS. 15 to 19 described above.

While the inventive concepts have been particularly shown and described with reference to example embodiments thereof, it will be understood that various changes in form and details may be made therein without departing from the scope of the following claims.

As used herein, the terms “comprises”, “comprising”, “includes”, “including”, “has”, “having” and any other variations thereof specify the presence of the stated features, steps, operations, elements, components, and/or groups but do not preclude the presence or addition of one or more other features, steps, operations, elements, components, and/or groups thereof. In addition, it will be understood that, although the terms “first”, “second”, “third”, etc. may be used herein to describe various elements, these elements should not be limited by these terms. Rather, these terms are only used to distinguish one element from another. For example, a first element could be termed a second element, and, similarly, a second element could be termed a first element, without departing from the scope of the present disclosure.

Relative terms, such as “lower” or “bottom” and “upper” or “top”, may be used herein to describe one element's relationship to another element as illustrated in the drawings. It will be understood that relative terms are intended to encompass different orientations of the device in addition to the orientation depicted in the drawings. For example, if the device in the drawings is turned over, elements described as being on the “lower” or “bottom” side of other elements would then be oriented on the “upper” or “top” side of the other elements. The example term “lower” can, therefore, encompass both an orientation of “lower” and “upper,” depending on the particular orientation of the figure. Similarly, the example term “bottom” can, therefore, encompass both an orientation of “bottom” and “top,” depending on the particular orientation of the figure.

What is claimed is:

1. A method of manufacturing a semiconductor device, the method comprising:
forming a mold stack by alternately forming a plurality of sacrificial layers and a plurality of mold insulating layers on a substrate;
forming a plurality of contact plug holes each extending in the mold stack in a vertical direction and spaced apart from a bottom surface of the mold stack by a first distance;
forming a photoresist layer on the mold stack and the plurality of contact plug holes;
forming a photoresist pattern by patterning the photoresist layer; and
extending ones of the plurality of contact plug holes in the vertical direction by etching the mold stack using the photoresist pattern,
wherein forming the photoresist pattern comprises removing a portion of the photoresist layer on the plurality of contact plug holes, and
wherein the photoresist pattern includes an opening exposing an upper surface of the mold stack and a side photoresist pattern on a sidewall of the mold stack.

2. The method of claim 1, wherein extending the ones of the plurality of contact plug holes in the vertical direction comprises removing the side photoresist pattern.

3. The method of claim 1, wherein the side photoresist pattern is spaced apart from the upper surface of the mold stack exposed through the opening by a predetermined distance.

4. The method of claim 1, wherein the side photoresist pattern comprises a first portion having a first width that is greater than or equal to 2 um.

5. The method of claim 4, wherein the side photoresist pattern further comprises a protrusion portion having a second width greater than the first width.

6. The method of claim 5, wherein the protrusion portion is adjacent to the upper surface of the mold stack.

7. The method of claim 1, wherein forming the photoresist layer, forming the photoresist pattern, and extending ones of the plurality of contact plug holes in the vertical direction are repeatedly performed.

8. The method of claim 1, wherein extending the ones of the plurality of contact plug holes in the vertical direction comprises removing a portion of the mold stack in the vertical direction so that the ones of the plurality of contact plug holes are spaced apart from the bottom surface of the mold stack by a second distance different from the first distance.

9. The method of claim 1, wherein extending the ones of the plurality of contact plug holes in the vertical direction comprises narrowing a width of at least a portion of each of the ones of the plurality of contact plug holes.

10. A method of manufacturing a semiconductor device, the method comprising:
forming a mold stack by alternately forming a plurality of sacrificial layers and a plurality of mold insulating layers on a substrate;
forming a hard mask on the mold stack;
forming a plurality of contact plug holes each extending in the mold stack and the hard mask in a vertical direction and spaced apart from a bottom surface of the mold stack by a first distance;
forming a photoresist layer on the mold stack, the hard mask, and the plurality of contact plug holes;
forming a photoresist pattern by patterning the photoresist layer; and
extending ones of the plurality of contact plug holes in the vertical direction by etching the mold stack using the photoresist pattern,
wherein forming the photoresist pattern comprises removing a portion of the photoresist layer on the plurality of contact plug holes, and
wherein the photoresist pattern includes an opening exposing an upper surface of the mold stack and a side photoresist pattern on a sidewall of the mold stack.

11. The method of claim 10, wherein the side photoresist pattern is spaced apart from the upper surface of the mold stack exposed through the opening by a predetermined distance.

12. The method of claim 10, wherein the side photoresist pattern comprises a protrusion portion adjacent to the upper surface of the mold stack.

13. The method of claim 10, wherein forming the photoresist layer, forming the photoresist pattern, and extending ones of the plurality of contact plug holes in the vertical direction are repeatedly performed.

14. The method of claim 10, wherein extending the ones of the plurality of contact plug holes in the vertical direction comprises removing a portion of the mold stack in the vertical direction so that the ones of the plurality of contact plug holes are spaced apart from the bottom surface of the mold stack by a second distance different from the first distance.

15. The method of claim 10, wherein extending the ones of the plurality of contact plug holes in the vertical direction comprises narrowing a width of at least a portion of each of the ones of the plurality of contact plug holes.

16. A method of manufacturing a semiconductor device, the method comprising:
forming a mold stack by alternately forming a plurality of sacrificial layers and a plurality of mold insulating layers on a substrate;
forming a stack cover insulating layer on the mold stack;
forming a plurality of contact plug holes each extending in the mold stack and the stack cover insulating layer in a vertical direction and spaced apart from a bottom surface of the mold stack by a first distance;
forming a photoresist layer on the mold stack and the plurality of contact plug holes;
forming a photoresist pattern by patterning the photoresist layer, the photoresist pattern including an opening exposing an upper surface of the mold stack and a side photoresist pattern on a sidewall of the mold stack;
extending ones of the plurality of contact plug holes in the vertical direction by etching the mold stack using the photoresist pattern;
forming an insulating spacer in the plurality of contact plug holes;
replacing the plurality of sacrificial layers with a plurality of gate electrodes;
exposing a top surface of each of the plurality of gate electrodes by removing a portion of the insulating spacer in each of the plurality of contact plug holes; and
forming a plurality of contact plugs in the plurality of contact plug holes, respectively, and electrically connected to the plurality of gate electrodes, respectively.

17. The method of claim 16, wherein forming the photoresist pattern comprises forming the side photoresist pattern such that the upper surface of the mold stack and a portion of the sidewall of the mold stack are exposed.

18. The method of claim 16, wherein the side photoresist pattern comprises a protrusion portion adjacent to the upper surface of the mold stack.

19. The method of claim 16, wherein forming the photoresist layer, forming the photoresist pattern, and extending ones of the plurality of contact plug holes in the vertical direction are repeatedly performed.

20. The method of claim 16, further comprising forming a hard mask on the mold stack.
